(19) United States
(12) Patent Application Publication
(10) Pub. No.: US 2009/0011194 A1
(43) Pub. Date: Jan. 8, 2009

(54) SUBSTRATE PROCESSING METHOD

(75) Inventors: Nicolas Nadaud, Paris (FR); Stephanie Roche, Paris (FR); Uwe Schmidt, Falkenberg (DE); Marcus Loergen, Zeuthen (DE)

Correspondence Address: OBLON, SPIVAK, MCCLELLAND MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 12/090,907

(22) PCT Filed: Oct. 23, 2006
(86) PCT No.: PCT/FR2006/051082

§ 371 Date: Sep. 5, 2008

(30) Foreign Application Priority Data
Oct. 25, 2005 (FR) 0553243

(51) Int. Cl. B32B 15/04; C23C 14/00; C23C 16/513

(52) U.S. Cl. 428/174; 204/192.11; 428/472; 428/450; 428/434; 427/569

(57) ABSTRACT

Method for the treatment of at least one surface portion of at least one layer A located between a substrate and a layer B of a thin-film multilayer, the layers of which are vacuum-deposited on the substrate having a glass function, according to the invention, is characterized in that:
at least one thin layer A is deposited on a surface portion of said substrate, this deposition phase being carried out by a vacuum deposition process;
using at least one linear ion source, a plasma of ionized species is generated from a gas or from a gas mixture;
at least one surface portion of the layer A is subjected to said plasma so that said ionized species at least partly modifies the surface state of the layer A; and
at least one layer B is deposited on a surface portion of the layer A, this deposition phase being carried out by a vacuum deposition process.

The present invention relates to a method of treating the surface of a substrate. It relates more particularly to treatment methods intended to be incorporated within a thin-film deposition installation and operating in a vacuum, such installations being of industrial size (substrates having dimensions perpendicular to the direction of movement of greater than 1.5 m, or even 2 m). More particularly, the invention relates to a surface treatment method that combines a thin-film deposition process (conventionally a sputtering, optionally a magnetically enhanced or magnetron sputtering, deposition line) and a method of treating the surface of these thin films using a linear ion source.

Of course, the invention also relates to the substrates thus treated and coated with a multilayer consisting of layers having different functionalities (solar control, low emissivity, electromagnetic shielding, heating, hydrophilic, hydrophobic and photocatalytic layers), layers modifying the level of reflection in the visible (antireflection or mirror layers) that incorporate an active system (electrochromic, electroluminescent or photovoltaic layers).

Typically, the thin-film multilayers deposited on a substrate having a glass function comprise an increasing number of thin layers, which correspondingly increases the number of interfaces between each layer. Each interface separating two films of different materials constitutes regions where it is essential to control the optical, thermal and mechanical properties of the entire multilayer.

Thus, it is for example well known that the field strength of a thin-film multilayer is determined by the energy of the bonds (chemical bonds, ionic bonds, Van Der Waals bonds, hydrogen bonds, etc.) at the interfaces. Likewise, the interfacial stresses, resulting from the volume stresses of the various layers, may also cause interfacial rupture, resulting in delamination of the coating at the interface most highly stressed or having the lowest adhesion energy.

It is also known that a second parameter characterizing the interface is its capacity to modify the crystallizability or at least to ensure medium-range order of the upper layer. This influence is of course used, for example in the microelectronic industry, to promote the quasi-monocrystalline growth or preferential orientation of grains within nanocrystalline thin films using a substrate of suitable crystallographic characteristics. This technique is generally called “epitaxial growth” and more precisely heteroepitaxial growth in the case in which the lower and upper materials are different.

The crystallographic characteristics and the grain morphology of the thin layers therefore determine the functionalities provided by the multilayers deposited on substrates having a glass function.

Thus, according to a first nonlimiting example, in the case of a multilayer having a self-cleaning functionality obtained by depositing a thin layer having photocatalytic properties (especially one based on titanium oxide), the performance of said layer is determined by the quantity of anatase titanium oxide phase contained in the functional layer.

As a second example, the performance of multilayers having a solar control functionality or an enhanced thermo insulation functionality (also called a low-E functionality) is determined by the capacity of the functional metallic layer to have a crystallization state favorable to reflection of radiation with a wavelength greater than the wavelength of the functional layer, which may for example be made of silver, this favorable crystallization state being very dependent on the crystallographic arrangement of the atoms forming the layer or layers deposited chronologically before the functional layer.

More generally, a thin-film multilayer structure deposited using a sputtering deposition line comprises at least one layer B called a functional layer deposited on at least one layer A.

Within the context of the invention, a layer A is defined as at least one layer, which may be a superposition of a plurality of layers Aᵢ (A₁, A₂, A₃, . . . Aₙ, where i is between 1 and n, and n is greater than or equal to 1).

The optimum performance of the multilayer is achieved where each of the elementary layers Aᵢ is as far as possible free of any contamination (for example adsorbed gas molecules) and has as smooth as possible a surface finish and an optimum material arrangement (low density of lattice-type crystal defects or dislocations, etc.).

The inventors have unfortunately found that, despite the care taken in the deposition steps, the surface of each of the layers Aᵢ may be:
(i) contaminated by the residual atmosphere (water, hydrocarbon) of the deposition device (magnetron) during transfer of the layer A between two deposition chambers, each provided with their own cathode;
(ii) the surface of a layer A deposited by magnetron sputtering does not always constitute an ideal surface for depositing a layer B, as it has, especially in the case of some materials, a certain roughness dependent on the nature of the material deposited, on the thickness of the layer and on the conditions under which the latter is deposited; and
(iii) it constitutes a crystallographically disturbed medium.

The object of the present invention is to alleviate the abovementioned drawbacks by providing a method for the treatment of a surface of at least one surface portion of a layer A lying within an A/B thin-film multilayer structure.

For this purpose, the method for the treatment of at least one surface portion of at least one layer A located between a substrate and a layer B of a thin-film multilayer, the layers of which are vacuum-deposited on the substrate having a glass function, according to the invention, is characterized in that:
at least one thin layer A is deposited on a surface portion of said substrate, this deposition phase being carried out by a vacuum deposition process;
using at least one linear ion source, a plasma of ionized species is generated from a gas or from a gas mixture;
at least one surface portion of the layer A is subjected to said plasma so that said ionized species at least partly modifies the surface state of the layer A; and
at least one layer B is deposited on a surface portion of the layer A, this deposition phase being carried out by a vacuum deposition process.

Thanks to these arrangements, it is possible for the nature of the surface of A to be substantially modified, this modification having an impact on the crystallization and/or grain morphology of the layer of type B deposited on the layer A within a thin-film deposition installation, this installation being of industrial size and operating in a vacuum.

In preferred embodiments of the invention, one or more of the following arrangements may optionally be furthermore used:
the linear ion source is positioned in the same compartment containing the vacuum deposition device for depositing the layer A;
the layer A comprises a plurality of superposed layers Aᵢ and in that at least one of the layers Aᵢ (where i is between 1 and n and n>1) is subjected to said plasma;
the surface treatment is carried out by one or more linear ion sources located one after another;
it is carried out by a sputter-up-and-down technique;
the linear ion source is positioned in a compartment isolated from that containing the vacuum deposition device for depositing the layer A;
the linear ion source is positioned at an angle between 30° and 90° to the plane of the substrate;
the deposition process consists of a sputtering, especially magnetically enhanced or magnetron sputtering, process;
the vacuum deposition process consists of a PECVD-based process (Plasma Enhanced Chemical Vapor Deposition);
the process involves a relative movement between the ion source and the substrate;
a gas plasma based on argon or on any inert gas, on oxygen or on nitrogen is used; and

the linear ion source generates a collimated ion beam with an energy between 0.05 and 2.5 keV, preferably between 1 and 2 keV.

According to another aspect of the invention, this also relates to substrates, especially glass substrates, at least one surface portion of which has been covered with a thin-film multilayer comprising layers having different functionalities (solar control, low emissivity, electromagnetic shielding, heating, hydrophobic, hydrophilic and photocatalytic layers), layers that modify the level of reflection in the visible (mirror and antireflection layers) or that incorporate an active system (electrochromic, electroluminescent or photovoltaic layers), at least one of the thin layers Aᵢ located beneath B having been treated by the method described above.

Other features and advantages of the invention will become apparent over the course of the following description, given by way of nonlimiting example.

In a preferred way of implementing the method which is the subject of the invention, this consists in inserting, into a line of industrial size for depositing thin films on a substrate, by cathode sputtering, especially magnetically enhanced or magnetron sputtering, and especially reactive sputtering in the presence of oxygen and/or nitrogen, at least one linear ion source.

The thin-film deposition may also be carried out by a process based on CVD (Chemical Vapor Deposition) or PECVD (Plasma Enhanced Chemical Vapor Deposition), which is well known to those skilled in the art and an example of its implementation is illustrated in document EP 0 149 408.

Within the context of the invention, the expression “industrial size” applies to a production line whose size is suitable, on the one hand, for operating continuously and, on the other hand, for handling substrates having one of its characteristic dimensions, for example the width perpendicular to the direction in which the substrate runs, of at least 1.5 m.

The linear ion source may be mounted either instead of a cathode, or at an airlock linking two deposition chambers, or more generally in a chamber forming part of a deposition line that is subjected to a high vacuum (for example one having a value of the order of 1×10⁻⁵ mbar).

It is possible to incorporate several sources within a production line, the sources being able to operate on just one side of a substrate or on each side of a substrate (up-and-down sputtering line for example), either simultaneously or consecutively and possibly each having their own mode of adjustment. A treatment is said to be a sputter-up-and-down treatment when it is carried out so that the ion beam is directed vertically or either upward or downward.

Use is made of at least one linear ion source whose operating principle is the following:

The linear ion source comprises, very schematically, an anode, a cathode, a magnetic device and a source for introducing gas. Examples of this type of source are described for example in RU 2 030 807, U.S. Pat. No. 6,002,208 or WO 02/093987. The anode is raised to a positive potential by a DC supply, the potential difference between the anode and the cathode causing a gas injected nearby to ionize.

The gas plasma is then subjected to a magnetic field (generated by permanent or nonpermanent magnets), thereby accelerating and focusing the ion beam.

The ions are therefore collimated and accelerated toward the outside of the source, and their intensity depends in particular on the geometry of the source, on the gas flow rate, on their nature and on the voltage applied to the anode.

In this case, according to the method which is the subject of the invention, the linear ion source operates in collimated mode with a gas mixture containing oxygen, argon, nitrogen and possibly an inert gas, such as for example neon or helium, as minor component.

It is preferred to use a gas whose chemical nature is adapted to the type of layer to be treated. An inert gas is preferably used, especially one based on argon, krypton or xenon, in order to avoid any chemical reaction with said surface. This is not the case for applications of the substrate-cleaning type where gases having a significant oxidizing power in the ionized state (especially oxygen) are preferred.

As nonlimiting example, oxygen is introduced with a flow rate of 150 sccm, with a voltage between the electrodes of 3 kV and an electrical current of 1.8 A, hence a consumed power of 5400 W (these figures relate to a source 1 m in length).

This source is positioned within the chamber and under the abovementioned conditions, in such a way that the collimated plasma containing the ionized species reaches at least one surface portion of a thin layer A deposited beforehand by a vacuum deposition technique on a portion of a substrate having a glass function moving through the treatment chamber.

It is therefore possible, on a surface portion of a layer A located on one of the faces of the substrate or on both faces of the same substrate (if several ion sources are used):
to treat the surface of the layer A that will be covered subsequently using a vacuum deposition technique with a layer B, this layer B then having its crystallization and/or its grain morphology controlled, or more generally in any one of one of the layers Aᵢ of a multilayer (A₁, A₂, A₃, . . . Aₙ) that will be covered with a functional layer B.

The substrate and its thin-film multilayer structure thus treated is in the form of a glass sheet, possibly curved, and possesses “industrial” dimensions. Within the context of the invention, “industrial” dimensions are understood to mean the characteristic dimensions of a sheet of glass commonly called in French PLF (i.e. full-width float) or DLF (i.e. half-width float), i.e. greater than 3 m in width and greater than 2 m in width, respectively.

The substrates and their multilayers thus treated may continue, without breaking vacuum, (that is to say the substrates remain within the vacuum deposition installation) their path through a chamber suitable for thin-film deposition by known processes of various technologies: PECVD, CVD (Chemical Vapor Deposition), magnetron sputtering or else ion plating, ion beam sputtering and dual ion beam sputtering.

Substrates, preferably transparent, flat or curved substrates, made of glass or of plastic (PMMA, PC, etc.) may be coated within a vacuum deposition installation as mentioned above with at least one thin-film multilayer conferring various functionalities, such as for example those defined above, on said substrate.

Thus, according to a first embodiment, the substrate has a coating of the “enhanced thermal insulation” or low-E (low-emissivity) type.

This coating consists of at least one sequence of at least five successive layers, namely a first layer based on metal oxide or semiconductor, chosen especially from tin oxide, titanium oxide and zinc oxide (with a thickness of between 10 and 30 nm), a layer of metal oxide or semiconductor, especially based on zinc oxide or titanium oxide, deposited on the first layer (with a thickness of between 5 and 20 nm), a silver layer (with a thickness of between 5 and 12 nm), a metal layer chosen especially from nickel chromium, titanium, niobium and zirconium, said metal layer being optionally nitrided (with a thickness of less than nm), and deposited on the silver layer, and at least one upper layer (with a thickness of between 5 and 40 nm) comprising a metal oxide chosen especially from tin oxide, titanium oxide and zinc oxide deposited on this metal layer, this upper layer (optionally consisting of a plurality of layers) being optionally of a protective layer called an overcoat.

Thus, in a second embodiment, the substrate has a coating of the “enhanced thermal insulation” or low-E or solar control type, suitable for undergoing heat treatments (of the toughening type), or coatings designed for applications specific to the automobile industry (also suitable for undergoing heat treatments).

This coating consists of a thin-film multilayer comprising an alternation of n functional layers B having reflection properties in the infrared and/or in solar radiation, based especially on silver (with a thickness of between 5 and 15 nm), and of (n+1) coatings A where n≧1, said coatings A comprising a layer or a superposition of layers made of a dielectric based in particular on silicon nitride (with a thickness of between 5 and 80 nm), or on a mixture of silicon and aluminum, or on silicon oxynitride, or on zinc oxide (with a thickness of between 5 and 20 nm), so that each functional layer B is placed between two coatings A, the multilayer also including layers that adsorb in the visible, especially based on titanium, on nickel chromium or on zirconium, these layers being optionally nitrided and located above and/or below the functional layer.

Thus, in a third embodiment, the substrate has a coating of the solar control type.

The substrate is provided with a thin-film multilayer comprising an alternation of one or more n functional layers having reflection properties in the infrared and/or in solar radiation, especially of an essentially metallic nature, and of (n+1) “coatings” with n≧1, said multilayer being composed, on the one hand, of one or more layers, including at least one made of a dielectric, especially based on tin oxide (with a thickness of between 20 and 80 nm), on zinc oxide, or metallic, or on nickel chromium oxide (with a thickness of between 2 and 30 nm), and, on the other hand, of at least one functional layer (with a thickness of between 5 and 30 nm) made of silver or a metal alloy containing silver, the (each) functional layer being placed between two dielectric layers.

Thus, in a fourth embodiment, the substrate has a coating of the solar control type, suitable for undergoing a heat treatment (for example of the toughening type).

This is a thin-film multilayer comprising at least one sequence of at least five successive layers, namely a first layer, especially based on silicon nitride (with a thickness of between 20 and 60 nm), a metal layer, based especially on nickel chromium or titanium (with a thickness of less than 10 nm) deposited on the first layer, a functional layer having reflection properties in the infrared and/or in solar radiation, especially based on silver (with a thickness of less than 10 nm), a metal layer chosen especially from titanium, niobium, zirconium and nickel chromium (with a thickness of less than 10 nm) deposited on the silver layer, and an upper layer based on silicon nitride (with a thickness of between 2 and 60 nm) deposited on this metal layer. Given below are examples of substrate coated with a low-E multilayer:

### EXAMPLE 1

### Substrate/SnO₂/TiO₂/ZnO/Ag/NiCr/ZnO/Si₃N₄/TiO₂

### EXAMPLE 2

### Substrate/SnO₂/ZnO/Ag/NiCr/ZnO/Si₃N₄/TiO₂

In examples 1 and 2, the layer B comprises silver and the layers A are at least one of the other layers of the multilayer that are located beneath the layer B.

As a variant of examples 1 and 2, and according to a second embodiment, the substrate includes a coating of the low-E type or solar control type, suitable for undergoing heat treatments (of the toughening type), or coatings designed for automobile-specific applications (which coatings are also suitable for undergoing heat treatments).

For example, given below are examples 3 and 4, which are suitable for undergoing heat treatments:

### EXAMPLE 3

### Substrate/Si₃N₄/ZnO/NiCr/Ag/ZnO/Si₃N₄

### EXAMPLE 4

### Substrate/Si₃N₄/ZnO/Ti/Ag/ZnO/Si₃N₄/ZnO/Ti/Ag/ZnO/Si₃N₄/TiO₂

In examples 3 and 4, the layer B comprises silver and the layers A are the other layers of the multilayer that are located beneath the layer B.

The deposition conditions for the multilayers forming the subject of examples 1 and 4 were the following:
an Si₃N₄ layer using an Si:Al target, with a power supply in pulsed mode (change-of-polarity frequency: 50 kHz) under a pressure of 2×10⁻³ mbar (0.2 Pa), a power of 2000 W, with 16 sccm Ar and 18 sccm N₂;
an SnO₂ layer using an Sn target, with a DC power supply, under a pressure of 4×10⁻³ mbar (0.4 Pa), a power of 500 W, with 30 sccm argon and 40 sccm oxygen;
a Zn:AlO layer deposited using a Zn:Al (2 wt % aluminum) target, with a DC power supply, under a pressure of 2×10⁻³ mbar (0.2 Pa), a power of 1500 W, 40 sccm Ar and 25 sccm O₂;
a TiO₂ layer deposited using a TiOₓ target, with a DC power supply, under a pressure of 2×10⁻³ mbar (0.2 Pa), a power of 2500 W, 50 sccm Ar and 3.0 sccm O₂;
a silver layer deposited using an Ag target, with a DC power supply, under a pressure of 2×10⁻³ mbar (0.2 Pa), a power of 120 W and 50 sccm argon;
a titanium layer deposited using a Ti target, with a DC power supply, under a pressure of 2×10⁻³ mbar (0.2 Pa),a power of 180 W and 50 sccm argon; and
an NiCr layer deposited using an Ni₈₀Cr₂₀ target, with a DC power supply, under a pressure of 2×10⁻³ mbar (0.2 Pa), a power of 200 W and 50 sccm argon.

As may be seen in the table below, the influence of the treatment of the interface by a linear ion source results in a significant increase in the crystallized phase to the detriment of the amorphous phase of the ZnO layer ([0002] orientation) and of the silver layer ([111] orientation), thus showing that the crystallographic properties of the silver are improved. This was experimentally correlated with a reduction in the resistivity of the silver layer. In examples 1 to 5, the ion source was used in a high-energy operating mode.

| | | | Area of | Area of | |
|---|---|---|---|---|---|
| | Layer A | | the ZnO | the Ag | |
| | treated | | [0002] | [111] | Resistance |
| | by the | | Bragg | Bragg | per square |
| Example | source¹ | Toughening | peak² | peak³ | (ohms) |
| E.1 | — | No | 13 | 48 | 5.0 |
| E.1 | TiO₂ | No | 22 | 127 | 4.8 |
| E.2 | — | No | 14 | 99 | 5.3 |
| E.2 | SnO₂ | No | 19 | 161 | 5.1 |
| E.3 | — | No | 7 | 13 | 7.7 |
| E.3 | — | Yes | 10 | 36 | 5.1 |
| E.3 | Si₃N₄ | No | 16 | 30 | 7.4 |
| E.3 | Si₃N₄ | Yes | 23 | 68 | 4.6 |
| E.4 | — | Yes | 32 | 69 | 4.4 |
| E.4 | ZnO | Yes | 40 | 118 | 4.0 |

¹treatment of an oxide layer: using argon as carrier gas, the operating conditions were the following: discharge voltage and current: 1060 V and 141 mA; carrier gas: 23 sccm Ar; total pressure = 1 mTorr;
Treatment of a nitride layer: ion source operating conditions: discharge voltage and current: 1500 V and 190 mA; carrier gas: 50 sccm N₂; total pressure = 1 mTorr;
²the area indicated is the sum of the contributions of the ZnO layers of the entire multilayer;
³in the case of example E.4, the area indicated is the sum of the contributions of the two Ag layers of the entire multilayer.

Thus, according to a fifth embodiment, the substrate comprised a coating of the type having a photocatalytic functionality.

Given below is an example of a substrate coated with this type of multilayer:

### EXAMPLE 5

### Substrate/SiO₂/BaTiO₃/TiO₂

The layer B was a TiO₂ layer and the layers Aᵢ were at least one of the layers located beneath the layer B.

The deposition conditions for the multilayer forming the subject of example 5 were the following:
a SiO₂ layer using an Si:Al target, with a power supply in pulsed mode (change-of-polarity frequency: 30 kHz) under a pressure of 2×10⁻³ mbar 20 (0.2 Pa), a power of 2000 W, and 15 sccm Ar and sccm O₂;
a BaTiO₃ layer using a BaTiO₃ target, with a radiofrequency power supply, under a pressure of 2×10⁻³ mbar (0.2 Pa), a power of 500 W and 50 sccm argon; and

a TiO₂ layer deposited using a TiOₓ target, with a DC power supply, under a pressure of 20×10⁻³ mbar (2.0 Pa), a power of 2500 W, 200 sccm Ar and 2.5 sccm O₂.

As may be seen in the table below, the influence of the treatment by the ion beam on the crystallographic characteristics of the titanium oxide layer and its photocatalytic performance before and after a toughening treatment.

| | | | Area of | Photocatalytic |
|---|---|---|---|---|
| | | | the TiO₂ | activity |
| | Layer Aᵢ | | [101] | detected by |
| | treated | | Bragg | the SAT test |
| | by the | | peak | (×10⁻³cm⁻¹ · |
| Example 5 | source | Toughening | (a.u.) | min⁻¹) |
| E.5 | — | No | 0.09 | 8 |
| E.5 | — | Yes | 0.60 | 28 |
| E.5 | BaTiO₃ | No | 0.17 | 17 |
| E.5 | BaTiO₃ | Yes | 0.72 | 36 |

* ion source conditions: discharge voltage and current: 1500 V and 118 mA; carrier gas: 20 sccm Ar; total pressure = 1 mTorr.

It is also possible to use the linear ion source in a low-energy operating mode.

Given below is a multilayer structure (example 6) treated according to this embodiment:

### EXAMPLE 6

### Low-Energy Treatment of a TiO₂ Layer: Multilayer of the Following Type Substrate/SnO₂/TiO₂/ZnO/Ag/NiCr/ZnO/Si₃N₄/TiO₂

As may be seen in the table below, the treatment by the low-energy (500 V) ion source results in a modification of the structure of layer A, in our case TiO₂. The treatment makes it possible in fact to generate nanoscale crystalline domains within a previously amorphous layer. This effect has repercussions on the crystallization of the silver, experimentally correlated with a reduction in the resistivity of this layer.

| | | TiO₂ | Resistance |
|---|---|---|---|
| TiO₂ layer | | crystallite | per square |
| treatment | TiO₂ structure | size | (ohms) |
| / | Amorphous | / | 5.5 |
| 500 V | Nanocrystallized | 2 nm | 5.3 |

The size of the crystallites was estimated using the Scherrer equation, assuming that the broadening of the peaks, measured by X-ray diffraction, was related only to the size of the crystallized domains (the peaks were simulated by a pseudo-Voigt function).

Some of these substrates were then capable of undergoing a heat treatment (bending, toughening, annealing) and were intended to be used in the automobile industry, especially a sunroof, a side window, a windshield, a rear window or a rearview mirror, or single or double glazing for buildings, especially interior or exterior glazing for buildings, a store showcase or counter, which may be curved, glazing for protecting objects of the painting type, an antidazzle computer screen, glass furniture, or any glass, especially transparent glass, substrate, in a general manner.

Given below are the operating conditions for measuring the photocatalytic activity by the SAT test.

The photocatalytic activity was measured in the following manner:
specimens measuring 5×5 cm² were cut;
specimens were cleaned for 45 minutes under UV irradiation and in a stream of oxygen;
the infrared spectrum was measured by FTIR or wavenumbers between 4000 and 400 cm⁻¹, in order to constitute a reference spectrum;
stearic acid was deposited: 60 microliters of a stearic acid solution, dissolved in an amount of 5 g/l in methanol, were deposited on the specimen by spin coating;
the infrared spectrum was measured by FTIR, and the area of the stretch bands of the CH₂-CH₃ bonds was measured between 3000 and 2700 cm⁻¹;
the specimens were subjected to UVA radiation: the power received by the specimen, about 35 W/m² and 1.4 W/m² for simulating outdoor and indoor exposure respectively, is controlled by a photoelectric cell in the 315-400 nm wavelength range. The nature of the lamps was also different depending on the illumination conditions: hot point fluorescent tubes, of Philips T12 reference, for indoor exposure and Philips Cleo Performance UV lamps for outdoor exposure;
the stearic acid layer was then photodegraded after successive exposure times of 10 minutes per measurement of the area of the stretch bands of the CH₂-CH₃ bonds between 3000 and 2700 cm⁻¹; and

the photocatalytic activity under outdoor conditions, kₒᵤₜ, was defined by the slope, expressed in cm⁻¹.min⁻¹, of the straight line representing the area of the stretch bands of the CH₂-CH₃ bonds between 3000 and 2700 cm⁻¹ as a function of UV exposure time, for a time between 0 and 30 minutes.

1: A method for the treatment of at least one surface portion of at least one layer A located between a substrate and a layer B of a thin-film multilayer, the layers of which are vacuum-deposited on the substrate having a glass function, characterized in that:
at least one thin layer A is deposited on a surface portion of said substrate by a vacuum deposition process;
using at least one linear ion source, a plasma of ionized species is generated from a gas or from a gas mixture;
at least one surface portion of the layer A is subjected to said plasma so that said ionized species at least partly modifies the surface state of the layer A; and
at least one layer B is deposited on a surface portion of the layer A by a vacuum deposition process.

2: The treatment method as claimed in claim 1, characterized in that the layer A comprises a plurality of superposed layers Aᵢ and in that at least one of the layers Aᵢ (wherein i is between 1 and n and n≧1, is subjected to said plasma.

3: The surface treatment method as claimed in claim 2, characterized in that the surface treatment is carried out by one or more linear ion sources located one after another.

4: The surface treatment method as claimed in claim 1, characterized in that it is carried out using the sputter-up-and-down technique.

5: The surface treatment method as claimed in claim 1, characterized in that the linear ion source is positioned in the same compartment containing the vacuum deposition device for depositing the layer A.

6: The surface treatment method as claimed in claim 1, characterized in that the linear ion source is positioned in a compartment isolated from that containing the vacuum deposition device for depositing the layer A.

7: The surface treatment method as claimed in claim 1, characterized in that the linear ion source is positioned at an angle between 30° and 90° to the plane of the substrate.

8: The surface treatment method as claimed in claim 1, characterized in that the deposition process consists of a magnetically enhanced sputtering, or a magnetron sputtering process.

9: The surface treatment method as claimed in claim 1, characterized in that the vacuum deposition process consists of a PECVD-based process.

10: The surface treatment method as claimed in claim 1, characterized in that a gas plasma is used which is based on a noble gas, on oxygen or on nitrogen.

11: The surface treatment method as claimed in claim 1, characterized in that the linear ion source generates a collimated ion beam having an energy between 0.05 and 2.5 keV.

12: A substrate obtained by implementing the method as claimed in claim 1, characterized in that the substrate is provided with a multilayer coating having a high reflection for thermal radiation, the coating of which consists of at least one sequence of at least five successive layers, namely:
a first layer based on a tin or titanium oxide;
a layer of zinc oxide deposited on the first layer;
a silver layer;
a metal layer chosen from nickel chromium, titanium, niobium and zirconium, deposited on the silver layer; and
an upper layer comprising a metal oxide or semiconductor, chosen from tin oxide, zinc oxide and titanium oxide, deposited on the metal layer.

13: A substrate obtained by implementing the method as claimed in claim 1, characterized in that the substrate is provided with a thin-film multilayer comprising an alternation of n functional layers B having reflection properties in the infrared and/or in solar radiation, based on silver, and of (n+1) coatings A where n≧1, said coatings A comprising a layer or superposition of layers of a dielectric based on silicon nitride, or on a mixture of silicon and aluminum, or on silicon oxynitride, or on zinc oxide, so that each functional layer B is placed between two coatings A, the multilayer also including layers that adsorb in the visible, based on titanium, on nickel chromium or on zirconium, these layers being optionally nitrided and located above and/or below the functional layer.

14: A substrate obtained by implementing the method as claimed in claim 1, characterized in that the substrate is provided with a thin-film multilayer comprising an alternation of n functional layers B having reflection properties in the infrared and/or in solar radiation, of essentially metallic nature, and of (n+1) layers A, where n≧1, said multilayer being composed, on the one hand, of one or more layers, including at least one layer made of a dielectric, based on tin oxide or metallic, or nickel chromium oxide, and, on the other hand, of at least one functional layer made of silver or of a metal alloy containing silver, wherein each functional layer is placed between two dielectric layers.

15: A substrate obtained by implementing the method as claimed in claim 1, characterized in that it comprises a thin-film multilayer comprising at least one sequence of at least five successive layers, namely:
a first layer, based on silicon nitride;
a layer, based on nickel chromium or on titanium, deposited on the first layer;
a functional layer having reflection properties in the infrared and/or in solar radiation, based on silver;
a metal layer, chosen from nickel chromium, titanium, niobium and zirconium, on the silver layer; and an upper layer based on silicon nitride, deposited on the metal layer.

16: A substrate obtained by implementing the method as claimed in claim 1, characterized in that the substrate is provided with a thin-film multilayer having self-cleaning properties, which comprises at least one functional layer comprising TiO₂ and a barrier sublayer of heteroepitaxial purpose.

17: The substrate as claimed in claim 12, characterized in that it is a substrate intended for a sunroof, a side window, a windshield, a rear window or a rearview mirror of an automobile, or single or double glazing for interior or exterior glazings for buildings, a store showcase or counter, glazing for protecting objects of the painting type, an antidazzle computer screen, or glass furniture.

18: The substrate as claimed in claim 17, characterized in that it is curved.
